(19) United States
(12) Patent Application Publication
(10) Pub. No.: US 2003/0205202 A1
(43) Pub. Date: Nov. 6, 2003

(54) PLASMA CVD DEVICE

(75) Inventors: KATSUNORI FUNAKI, TOKYO (JP); SHIN HIYAMA, TOKYO (JP)

Correspondence Address: OLIFF & BERRIDGE, PLC, P.O. BOX 19928, ALEXANDRIA, VA, 22320, US

(73) Assignee: Kokusai Electric Co., LTD.

(21) Appl. No.: 09/219,706

(22) Filed: Dec. 23, 1998

(30) Foreign Application Priority Data
Jan. 5, 1998 (JP) 10-000487

(51) Int. Cl. C23C 16/00

(52) U.S. Cl. 118/723 E

(57) ABSTRACT

It is an object of the present invention to provide a plasma CVD device in which it is possible to inhibit the formation of particles resulting from the adhesion of reaction by-products of poor adhesive strength around the upper electrode.

The plasma CVD device has a vacuum container 200, an upper electrode 210 and a lower electrode 220. The edge of the gas dispersion plate 213 of the upper electrode 210 is formed in the shape of an upturned bowl, the edge of which extends below the upper surface of the treatment substrate W mounted on the substrate-mounting surface 221 of the lower electrode 220.

### BACKGROUND OF THE INVENTION

1. Field of the Invention

The present invention relates to a parallel flat type plasma CVD (Chemical Vapour Deposition) device, and in particular to a CVD device in which parallel flat electrodes are arranged horizontally.

2. Description of the Related Art

Generally speaking, in order to manufacture semiconductor, liquid crystal display and other solid devices it is necessary to use a coating device to form a prescribed thin film on the surface of the substrate of the solid device (wafer in the case of a semiconductor device, glass substrate in the case of a liquid crystal display device, etc.)

One type of coating device is the CVD device. This employs a chemical reaction to form a prescribed thin film. An example of such a CVD device is provided by the plasma CVD device, which uses plasma as activating energy to promote the chemical reaction.

One such plasma CVD device is the high-frequency discharge type. This uses a high-frequency power source as the power source to form the plasma. An example of a plasma CVD device of this kind is the parallel flat type which employs parallel flat electrodes for the purpose of forming the plasma. In a horizontal parallel flat type plasma CVD the parallel flat electrodes are arranged horizontally.

FIG. 15 is a lateral cross-sectional diagram illustrating the structure of a conventional plasma CVD device. It utilises horizontal parallel flat electrodes and a high-frequency power source for the purpose of forming the plasma.

In the plasma CVD device illustrated here, two flat electrodes 110, 120 are arranged within a vacuum container 100. High-frequency electric power is impressed between these electrodes in order to convert reaction gases into plasma. The reaction gases are excited by this plasma and thus form a prescribed thin film on a treatment substrate W.

An example of a prescribed thin film which can be formed with the aid of this plasma CVD device is an amorphous silicon film (a-Si film). SiH₄ and H₂ gases are normally used as reaction gases in the formation of this amorphous silicon film.

However, with the abovementioned conventional plasma CVD device, formation of the amorphous silicon film is accompanied by adhesion of pulverulent reaction by-products around the upper electrode 110. These reaction by-products present a problem because they are poor in terms of adhesive strength and result in the formation of particles.

### SUMMARY OF THE INVENTION

It is an object of the present invention to provide a plasma CVD device in which it is possible to inhibit the formation of particles resulting from the adhesion of reaction by-products of poor adhesive strength around the upper electrode.

With the aim of presenting a solution to the abovementioned problem, the plasma CVD device according to claim 1 is designed to inhibit the formation of particles resulting from the adhesion of reaction by-products of poor adhesive strength around the upper electrode by ensuring that the edge of the upper electrode extends below the upper surface of the treatment substrate located on the upper surface of the lower electrode.

In other words, in the plasma CVD device according to claim 1, which impresses electric power between an upper electrode and a lower electrode arranged horizontally so as to face each other, thus producing plasma from reaction gases for use in film deposition, the reaction gases being excited by this plasma to form a prescribed thin film on the surface of a treatment substrate located on the upper surface of the lower electrode, the edge of the upper electrode extends below the upper surface of the treatment substrate located on the upper surface of the lower electrode.

The fact that in the plasma CVD device according to claim 1 the edge of the upper electrode extends below the upper surface of the treatment substrate located on the upper surface of the lower electrode makes it possible to reduce the amount of reaction by-products of poor adhesive strength which are present above the treatment substrate. This is because a strongly adhesive thin film is formed on the discharge surface of the upper electrode, but reaction by-products of poor adhesive strength fail to adhere to it. In this manner the occurrence of particles which result from falling reaction by-products is inhibited. As a result, adulteration of the treatment substrate through particle adhesion is inhibited, and the yield can be improved.

The plasma CVD device according to claim 2 is essentially the same as the device according to claim 1, except that an insulator is located on the edge of the upper electrode.

The fact that in the plasma CVD device according to claim 2 an insulator is located on the edge of the upper electrode makes it possible to prevent the occurrence of localised discharges on this edge.

The plasma CVD device according to claim 3 is essentially the same as the device according to claim 2, except that the insulator is fashioned in such a manner that of a plurality of surfaces thereof the surface which comes into contact with the reaction gas during film deposition does not face upwards.

The fact that in the plasma CVD device according to claim 3 the insulator is fashioned in such a manner that the surface which comes into contact with the gas does not face upwards makes it possible during film deposition to prevent reaction by-products adhering to the surface which comes into contact with the gas from rising upwards with vapour currents. In this manner it is possible to inhibit the occurrence of particles resulting from rising reaction by-products.

The plasma CVD device according to claim 4 is essentially the same as the device according to claim 2, except that the insulator is fashioned in such a manner that of a plurality of surfaces thereof the surface which comes into contact with the reaction gas during film deposition does not face the conveyance route of this treatment substrate during conveyance thereof.

The fact that in the plasma CVD device according to claim 4 the insulator is fashioned in such a manner that the surface which comes into contact with the gas does not face the conveyance route of this treatment substrate during conveyance thereof makes it possible during conveyance of the treatment substrate to prevent reaction by-products adhering to the surface which comes into contact with the gas from rising upwards even if vapour currents occur in the vicinity of the insulator as a result of this conveyance. In this manner it is possible to inhibit the occurrence of particles resulting from rising reaction by-products.

The plasma CVD device according to claim 5 is essentially the same as the device according to claim 1, except that the discharge surface on the edge of the upper electrode is insulated.

The fact that in the plasma CVD device according to claim 5 the discharge surface on the edge of the upper electrode is insulated makes it possible to inhibit discharge in the neighbourhood of the treatment substrate. This in turn makes it possible to ensure that plasma density above the treatment substrate is not reduced in spite of the increased area of the discharge surface which results from the extension on the edge of the upper electrode. The consequent ability to prevent reduced efficacy of plasma treatment above the treatment substrate means it is possible to ensure that there is no deterioration in the distributional characteristics of film thickness.

Moreover, this structure makes it possible to prevent increased introduction of electrons into the thin film which is formed on the surface of the treatment substrate. This in turn makes it possible to ensure that there is no increased film stress caused by the introduction of large amounts of electrons. As a result, it is possible to prevent peeling of the thin film which is formed on the surface of the treatment substrate.

The plasma CVD device according to claim 6 is essentially the same as the device according to claim 5, except that the discharge surface on the edge of the upper electrode is divided into two discharge surfaces in the shape of a ring around the centre axis of the upper electrode, the inner discharge surface being insulated by means of an insulator while the outer discharge surface is insulated by means of insulating treatment.

The fact that in the plasma CVD device according to claim 6 insulation of the inner discharge surface is implemented with the aid of an insulator makes it possible to enhance the effect of inhibiting discharge in the neighbourhood of the treatment substrate as compared with insulation through insulation treatment.

Moreover, the fact that insulation of the outer discharge surface in this plasma CVD device is implemented with the aid of insulation treatment makes it possible, more effectively than would be the case if it were insulated by means of an insulator, to ensure that there is no adhesion of reaction by-products of poor adhesive strength around the insulator which is located on the inner discharge surface. In addition, this structure makes it possible to ensure that there is no adhesion of reaction by-products of poor adhesive strength on the outer discharge surface either. Furthermore, since all that happens on the outer discharge surface is that plasma density is lowered, there is no risk of adhesion of reaction by-products of poor adhesive strength.

The plasma CVD device according to claim 7 is essentially the same as the device according to claim 1, except that the discharge surface on the edge of the upper electrode becomes progressively broader as it proceeds downwards.

The fact that in the plasma CVD device according to claim 7 the discharge surface on the edge of the upper electrode becomes progressively broader as it proceeds downwards means that there is no risk of obstruction of the flow of cleaning gas at the edge of this upper electrode during gas cleaning despite the fact that it extends downwards. As a result, film which has formed on the discharge surface of the upper electrode can easily be removed by means of gas cleaning with plasma.

The plasma CVD device according to claim 8 is essentially the same as the device according to claim 1, except that the insulator is fashioned in such a manner that of a plurality of surfaces thereof the surface which comes into contact with the reaction gas during film deposition forms an extension of the discharge surface on the edge of the upper electrode.

The fact that in the plasma CVD device according to claim 8 the insulator is fashioned in such a manner that the surface which comes into contact with the reaction gas during film deposition forms an extension of the discharge surface on the edge of the upper electrode makes it possible to ensure that there is no risk of obstruction of the flow of gas on this surface which comes into contact with the reaction gas. As a result, it is possible to inhibit adhesion of reaction by-products to this surface during film deposition, and to etch effectively those reaction by-products which have adhered to it during gas cleaning. This means that the time required for gas cleaning can be shortened.

The plasma CVD device according to claim 9 is essentially the same as the device according to claim 1, except that the edge of the upper electrode extends below the conveyance route of the treatment substrate and is divided horizontally in the vicinity of this conveyance route.

The fact that in the plasma CVD device according to claim 9 the edge of the upper electrode extends below the conveyance route of the treatment substrate and is divided horizontally in the vicinity of this conveyance route makes it possible to avoid widening the aperture of the vacuum container during substrate conveyance in spite of the fact that the edge of the upper electrode extends below the conveyance route of the treatment substrate.

The plasma CVD device according to claim 10 is essentially the same as the device according to claim 1, except that the upper electrode is divided horizontally in one place or more and electric power is supplied independently to each divided area.

The fact that in the plasma CVD device according to claim 10 the upper electrode is divided horizontally in one place or more and power is supplied independently to each divided area means that during gas cleaning of the interior of the vacuum container with plasma it is possible to supply a greater amount of electric power to those parts where cleaning is slow. This allows cleaning to be implemented with increased efficiency.

The plasma CVD device according to claim 11 is essentially the same as the device according to claim 1, except that the vacuum container for use in film deposition is of a twin-tank structure having an inner tank and an outer tank, the upper electrode and the lower electrode being located within the inner tank.

Thus, the plasma CVD device according to claim 1 has a characteristically structured edge on the upper electrode, which can be adapted for use with a device of double-tank as well as single-tank structure.

### BRIEF DESCRIPTION OF THE DRAWINGS

FIG. 1 is a lateral cross-sectional diagram illustrating a first embodiment of the plasma CVD device to which the present invention pertains;

FIG. 2 is a lateral cross-sectional diagram explaining the action of the first embodiment;

FIG. 3 is a lateral cross-sectional diagram illustrating an example of the detailed structure of the first embodiment;

FIG. 4 is a lateral cross-sectional diagram illustrating the structure of part of the detailed structure of the first embodiment;

FIG. 5 is a lateral cross-sectional diagram explaining the action of the detailed structure of the first embodiment;

FIG. 6 is a lateral cross-sectional diagram illustrating a second embodiment of the plasma CVD device to which the present invention pertains;

FIG. 7 is a lateral cross-sectional diagram illustrating an example of the detailed structure of the second embodiment;

FIG. 8 is a lateral cross-sectional diagram illustrating a third embodiment of the plasma CVD device to which the present invention pertains;

FIG. 9 is a lateral cross-sectional diagram illustrating a fourth embodiment of the plasma CVD device to which the present invention pertains;

FIG. 10 is a lateral cross-sectional diagram for the purpose of explaining the effects of the fourth embodiment;

FIG. 11 is a lateral cross-sectional diagram for the purpose of explaining the effects of the fourth embodiment;

FIG. 12 is a lateral cross-sectional diagram illustrating an example of the detailed structure of the fourth embodiment;

FIG. 13 is a lateral cross-sectional diagram illustrating a fifth embodiment of the plasma CVD device to which the present invention pertains;

FIG. 14 is a lateral cross-sectional diagram for the purpose of explaining the action of the fifth embodiment; and

FIG. 15 is a lateral cross-sectional diagram illustrating the structure of a conventional plasma CVD device.

### DESCRIPTION OF THE PREFERRED EMBODIMENTS

There follows, with reference to the drawings, a detailed description of the preferred embodiments of the plasma CVD device to which the present invention pertains.

1. First Embodiment

1.1 Structure

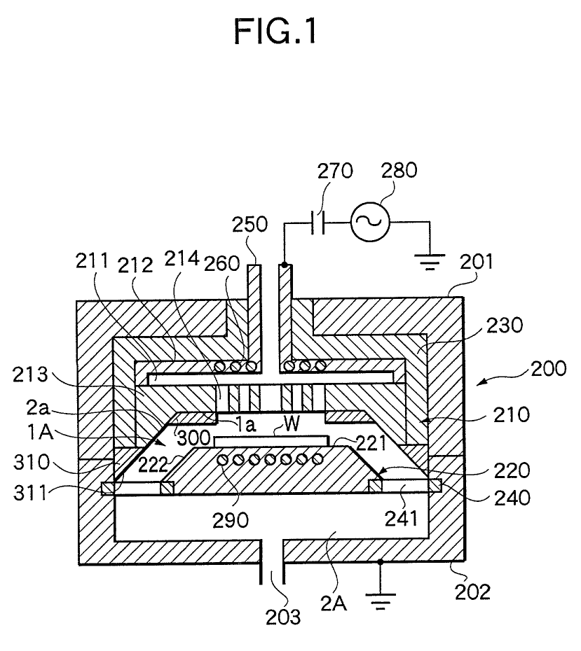

FIG. 1 is a lateral cross-sectional diagram illustrating a first embodiment of the plasma CVD device to which the present invention pertains. It should be added that FIG. 1 shows a typical example of a case in which the present invention is applied to a plasma CVD device having a vacuum container of single-tank structure.

The plasma CVD device illustrated in the drawing has a vacuum container 200. This vacuum container 200 is formed, for instance, in the shape of a rectangular box. It is divided horizontally into an upper container 201 and a lower container 202. The upper container 201 is fixed in a predetermined position, while the lower container 202 can be raised and lowered with the aid of a raising and lowering mechanism which is not shown in the drawing.

Within the vacuum container 200 are located an upper electrode 210 and a lower electrode 220, constituting a pair of parallel flat electrodes. These are arranged horizontally and in such a manner as to face each other. The upper electrode 210 is supported on the upper container 201 with the aid of an insulator 230 made, for instance, of quartz. The lower electrode 220 is supported on the lower container 202 with the aid of a ring-shaped supporting plate 240. In this case, the lower electrode 220 is arranged in such a manner as to divide the interior of the vacuum container 200 into a reaction chamber 1A and an exhaust chamber 2A.

The upper electrode 210 is formed in the shape of a box. The interior of this box-shaped upper electrode 210 forms a gas dispersion unit 211, the purpose of which is to disperse reaction, cleaning and other gases. To the top plate 212 of this upper electrode 210 is connected a gas supply unit 250, the purpose of which is to supply reaction and other gases to the gas dispersion unit 211. Meanwhile, there is embedded in this top plate 212 a heater wire 260, the purpose of which is to heat the reaction and other gases. In the bottom plate 213 of this upper electrode 210 is formed a plurality of gas dispersion holes 214. This bottom plate 213 will be referred to below as the gas dispersion plate.

On the upper surface of the lower electrode 220 is fashioned a substrate-mounting surface 221. The substrate W which is to be treated is mounted on this substrate-mounting surface 221 during film deposition. This substrate-mounting surface 221 is located in the vicinity of the position where the vacuum container 200 is divided. In other words, it is fashioned in the vicinity of the substrate conveyance route. A heater wire 290, the purpose of which is to heat the treatment substrate during film deposition, is embedded in this lower electrode 220.

In the supporting plate 240 of the lower electrode 220 is formed a plurality of exhaust holes 241, the purpose of which is to expel the ambient atmosphere of the reaction chamber 1A into the exhaust outlet 2A. Meanwhile, in the bottom plate of the vacuum container 200 is formed an exhaust hole 203, the purpose of which is to expel the ambient atmosphere of the exhaust chamber 2A.

To the gas supply unit 250 is connected a high-frequency power source 280 by way of a direct-current blocking capacitor 270. Thus the upper electrode 210 is connected to the high-frequency power source 280 by way of the direct-current blocking capacitor 270. Meanwhile, the lower container 202 of the vacuum container 200 is earthed. Thus the lower electrode 220 is earthed by way of the supporting plate 240 and the lower container 202. This allows high-frequency electric power to be impressed between the upper electrode 210 and the lower electrode 220 during film deposition.

The gas dispersion plate 213 is formed in the shape of an upturned bowl. The edge of this gas dispersion plate 213 extends below the upper surface of the treatment substrate W mounted on the substrate-mounting surface 221. The drawing shows the edge of the gas dispersion plate 213 extending to the vicinity of the treatment substrate W. It also shows this edge extending almost as far as the substrate conveyance route (the vicinity of the position where the vacuum container 200 is divided).

The discharge surface on the edge of the gas dispersion plate 213 is fashioned in such a manner that it becomes progressively broader as it proceeds downwards. This discharge surface is divided into two in the shape of a ring around the centre axis of the gas dispersion plate 213. The inner discharge surface 1a is fashioned horizontally, while the outer discharge surface 2a is fashioned in such a manner as to form an angle in excess of 90 degrees to the inner discharge surface 1a. The inner discharge surface 1a will be referred to below as the ‘horizontal section’, and the outer discharge surface 2a as the ‘oblique section’. The lateral surface 222 of the lower electrode 220 is fashioned in such a manner as to be parallel with the oblique section 2a.

A ring-shaped insulator 300 formed of alumina or a similar substance is attached to the horizontal section la of the discharge surface on the edge of the gas dispersion plate 213, while the oblique section 2a is subjected to insulation treatment by means of alumina spraying, alumite treatment or an equivalent process.

On the edge of the gas dispersion plate 213 is located a ring-shaped insulator 310, which is formed of alumina or a similar substance. This ring-shaped insulator 310 is attached, for instance, to the lower container 202. The surface 311 of this ring-shaped insulator 310 which comes into contact with the reaction and other gases during film deposition is inclined in such a manner as to be more or less parallel with the lateral surface 222 of the lower electrode 220. The above is the structure of the first embodiment.

1.2 Action

There follows a description of the actions involved in forming a prescribed thin film on the treatment substrate W and in gas cleaning with the abovementioned structure. Firstly, the action involved in film deposition will be described.

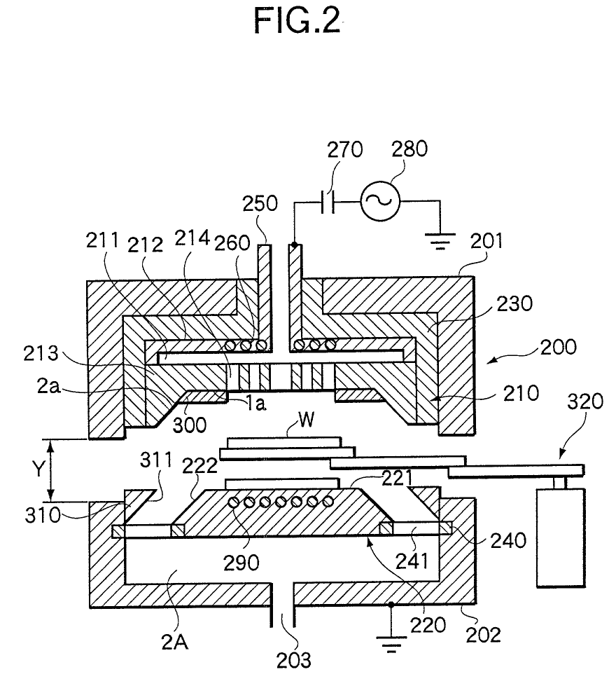

To begin with, as may be seen in FIG. 2, the lower container 202 is lowered with the aid of a raising and lowering mechanism which is not shown in the drawing. This allows the vacuum container 200 to open. Next, a substrate conveyance device 320 is used to convey the substrate W which is to be treated into the vacuum container 200, where it is mounted on the substrate-mounting surface 221 which is fashioned on the upper surface of the lower electrode 220. The lower container 202 is then raised with the aid of the raising and lowering mechanism which is not shown in the drawing. This allows the vacuum container 200 to close in the manner illustrated in FIG. 1.

Next, the ambient atmosphere contained within the vacuum container 200 is expelled through the exhaust outlet 203. This allows the interior of the vacuum container 200 to assume the state of a predetermined vacuum.

Once the interior of the vacuum container 200 has assumed the predetermined vacuum state, reaction gas for use in film deposition is fed through the gas supply unit 250 into the gas dispersion unit 211. The reaction gas which has been fed into the gas dispersion unit 211 is now dispersed through the gas dispersion holes 214 to the area between the electrodes 210, 220. Meanwhile, the ambient atmosphere continues to be expelled from within the vacuum container 200. To this end, the pressure within the vacuum container 200 is monitored, and the amount of ambient atmosphere expelled is controlled in accordance with the results of the monitoring. In this manner the pressure within the vacuum container 200 is set at the predetermined level.

When the pressure within the vacuum container 200 reaches the predetermined level, high-frequency electric power from the high-frequency power source 280 is impressed between the electrodes 210, 220. This serves to convert the reaction gas into plasma. The molecules of the reaction gas are excited by this plasma, as a result of which the prescribed thin film is formed on the surface of the treatment substrate W. Unreacted gas is expelled by way of the exhaust holes 241, exhaust chamber 2A and exhaust outlet 203.

Once the prescribed thin film has been formed on the surface of the treatment substrate W, the supply of reaction gas is halted. Next, as FIG. 2 shows, the lower container 202 is lowered with the aid of the raising and lowering mechanism. This allows the vacuum container 200 to open. Then, as FIG. 2 shows, the substrate conveyance device 320 conveys the treatment substrate W out of the vacuum container 200. The same treatment is then performed on the next treatment substrate W, and this is repeated with each subsequent treatment substrate W.

The above is the action involved in film deposition. There follows an explanation of the action involved in gas cleaning.

In this case, the ambient atmosphere is expelled from the vacuum container 200 to create a vacuum without mounting a treatment substrate W on the substrate-mounting surface 221 of the lower electrode 220. Once the interior of the vacuum container 200 has assumed the predetermined vacuum state, cleaning gas for use in gas cleaning is fed through the gas supply unit 250 into the gas dispersion unit 211. The cleaning gas which has been fed into the gas dispersion unit 211 is now dispersed by way of the gas dispersion plate 213 to the area between the electrodes 210, 220. Meanwhile, the ambient atmosphere continues to be expelled from within the vacuum container 200. To this end, the amount of ambient atmosphere expelled is controlled so that the pressure within the vacuum container 200 may reach the predetermined level.

Once the pressure within the vacuum container 200 has reached the predetermined level, high-frequency electric power is impressed between the electrodes 210, 220. This serves to convert the cleaning gas into plasma. The molecules of the cleaning gas are excited by this plasma, so that the thin film formed on the discharge surface of the gas dispersion plate 213 and the reaction by-products which have adhered to the surface 311 of the insulator 310 which comes into contact with the gas are etched. The etched thin film and reaction by-products are expelled by way of the exhaust holes 241, exhaust chamber 2A and exhaust outlet 203. The above is the action involved in gas cleaning.

1.3 Effects

The embodiment which has been described in detail above allows the following effects to be obtained.

In the first place, the fact that in the present embodiment the edge of the gas dispersion plate 213 of the upper electrode 210 extends below the upper surface of the treatment substrate W mounted on the substrate-mounting surface 221 of the lower electrode 221 makes it possible to reduce the amount of reaction by-products which are present above the upper surface of the treatment substrate W. This is because the reaction by-products are poor in terms of adhesive strength and therefore do not adhere to the discharge surface of the gas dispersion plate 213. The thin film, on the other hand, is formed successfully because it is strongly adhesive.

In this manner it is possible to inhibit the occurrence of particles which result from falling reaction by-products. Since this makes it possible to inhibit the adulteration of the treatment substrate W through particle adhesion, it follows that the yield of substrates W can be improved.

Moreover, this ability to inhibit the adulteration of the treatment substrate W through particle adhesion makes it possible to extend the maintenance cycle of the plasma CVD device, thus improving throughput.

In the second place, the fact that in the present embodiment the insulator 310 is located on the edge of the gas dispersion plate 213 makes it possible to inhibit the occurrence of localised discharge despite the fact that the edge of the gas dispersion plate 213 extends parallel with the insulator 230.

In the third place, the fact that in the present embodiment the surface 311 of the insulator 310 which comes into contact with the gas forms an angle in excess of 90 degrees to the horizontal surface means it is possible to ensure that this surface 311 which comes into contact with the gas does not face upwards. In this manner it is possible to prevent reaction by-products adhering to this surface 311 which comes into contact with the gas from rising upwards with vapour currents. As a result it is possible to inhibit the occurrence of particles resulting from rising reaction by-products.

In the fourth place, the fact that in the present embodiment the insulator 310 is attached to the lower container 202 means it is possible to ensure that the surface 311 of the insulator 310 which comes into contact with the gas does not face the conveyance route of the treatment substrate W during conveyance thereof (conveyance into and out of the vacuum container 200).

This makes it possible during conveyance of the treatment substrate W to prevent reaction by-products adhering to the surface 311 of the insulator 310 which comes into contact with the gas from rising upwards even if vapour currents occur in the vicinity of the insulator 310 as a result of this conveyance of the treatment substrate W. In this manner it is possible to inhibit the occurrence of particles resulting from rising reaction by-products.

In the fifth place, the fact that in the present embodiment the discharge surface on the edge of the gas dispersion plate 213 is insulated makes it possible to inhibit discharge in the neighbourhood of the treatment substrate W despite the fact that the edge of the gas dispersion plate 213 extends further than conventionally. This in turn makes it possible to ensure that plasma density above the treatment substrate W is not reduced. The consequent ability to prevent reduced efficacy of plasma treatment above the treatment substrate W means it is possible to ensure that there is no deterioration in the distributional characteristics of film thickness.

In the sixth place, the fact that in the present embodiment the discharge surface on the edge of the gas dispersion plate 213 is insulated also makes it possible essentially to inhibit any increase in the area of the discharge surface despite the fact that the edge of the gas dispersion plate 213 extends further than conventionally. This in turn makes it possible to ensure that there is no increased film stress caused by the introduction of large amounts of electrons into the thin film which is formed on the surface of the treatment substrate W. As a result, it is possible to prevent peeling of the thin film which is formed on the surface of the treatment substrate W.

In the seventh place, the fact that in the present embodiment insulation of the horizontal section la of the discharge surface on the edge of the gas dispersion plate 213 is implemented with the aid of an insulator 300 makes it possible to enhance the effect of inhibiting discharge in the neighbourhood of the treatment substrate W as compared with insulation through insulation treatment.

In the eighth place, the fact that in the present embodiment insulation of the oblique section 2a of the discharge surface on the edge of the gas dispersion plate 213 is effected by means of insulation treatment makes it possible, more effectively than would be the case if it were insulated by means of an insulator, to ensure that there is no adhesion of reaction by-products of poor adhesive strength to the insulator 300 of the horizontal section 1a. In addition, this structure makes it possible to ensure that there is no adhesion of reaction by-products of poor adhesive strength to the oblique section 2a either. This is because a structure of this sort makes it possible to guarantee a plasma density at which adhesion of reaction by-products to the oblique section 2a can be prevented.

In the ninth place, the fact that in the present embodiment the discharge surface on the edge of the gas dispersion plate 213 becomes progressively broader as it proceeds downwards means that there is no risk of obstruction of the flow of cleaning gas at the edge of this gas dispersion plate 213 during gas cleaning despite the fact that it extends downwards. As a result, film which has formed on the discharge surface of the upper electrode can easily be removed by means of gas cleaning with plasma.

In the tenth place, the fact that in the present embodiment the surface 311 of the insulator 310 which comes into contact with the reaction gas during film deposition is the same oblique surface as the oblique section 2a of the gas dispersion plate 213 allows the surface 311 which comes into contact with the reaction gas to form an extension of the oblique section 2a. This makes it possible to ensure that there is no risk of obstruction of the flow of gas on this surface 311 which comes into contact with the reaction gas. As a result, it is possible to inhibit adhesion of reaction by-products to this surface 311 during film deposition, and during gas cleaning to etch effectively those reaction by-products which have adhered to it. This means that the time required for gas cleaning can be shortened.

In the eleventh place, the fact that in the present embodiment the substrate-mounting surface 221 of the lower electrode 220 is located in the vicinity of the substrate conveyance route means that it is possible to decrease the width of the aperture Y (cf. FIG. 2) of the vacuum container 200.

In the twelfth place, the fact that in the present embodiment the interior of the reaction chamber 1A is maintained at a high temperature with the aid of the heater wires 260, 290 makes it possible to inhibit the creation of dust from deposits (thin film, reaction by-products etc.) which form in the interior of the reaction chamber 1A as a result of film deposition.

### 1.4 EXPERIMENTAL EXAMPLE

There follows a description of an experimental example of the present embodiment. An experiment was carried out in which a 650 mm H 550 mm glass substrate was mounted as a treatment substrate on the substrate-mounting surface 221 of the lower electrode 220. A vacuum was created within the reaction chamber 1A, and was maintained at 1×10⁻³ torr or below. 200 sccm each of SiH₄ gas and H₂ gas for use in film deposition were introduced into the reaction chamber 1A, after which high-frequency power was impressed at 13.56 MHz, 200 W between the electrodes 210, 220 to create plasma, and an amorphous silicon film was formed on the surface of the glass substrate.

As a result of the experiment, it was found that the number of particles adhering to the glass substrate in the plasma CVD device of the present embodiment had been reduced to 100/cm², as compared with 2000/cm² in a conventional plasma CVD device.

Moreover, while with the conventional plasma CVD device it required 15 minutes to etch all the amorphous silicon film and reaction by-products within the vacuum container after creating an amorphous silicon film with a thickness of 5000 Ångström/min, it proved possible to achieve this in nine minutes with the plasma CVD device of the present embodiment.

Furthermore, while film stress was 500 Mpa with the device of the present embodiment when the edge of the gas dispersion plate 213 was not insulated, it proved possible to reduce this even further to 50 Mpa when it was insulated as in the present embodiment.

Similarly, while uniformity of film thickness was 15% or above with the device of the present embodiment when the edge of the gas dispersion plate 213 was not insulated, it proved possible to reduce this to within 5% when it was insulated as in the present embodiment.

### 1.5 SPECIFIC EXAMPLE

1.5.1 Structure

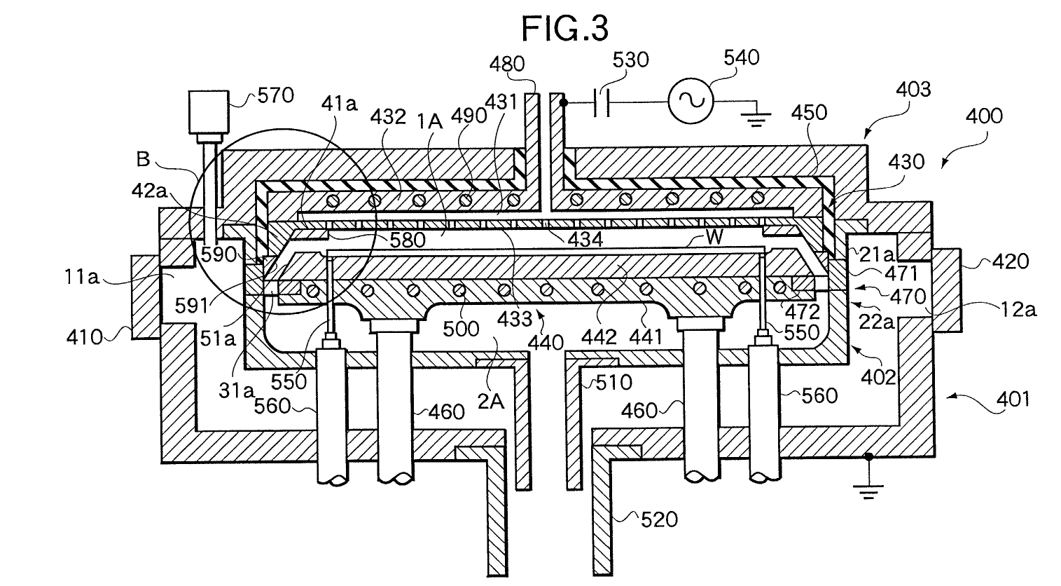

FIG. 3 is a lateral cross-sectional diagram illustrating an example of the detailed structure of the first embodiment. It should be pointed out that the drawing shows the present embodiment adapted to a plasma CVD device having a vacuum container with a twin-tank structure.

The plasma CVD device illustrated in the drawing has a vacuum container 400 with a twin-tank structure. This vacuum container 400 has an outer tank body 401 which forms the side walls and bottom plate of the outer tank, an inner tank body 402 which forms the side walls and bottom plate of the inner tank, and a top plate 403 which is shared by both the outer and inner tanks.

In the side walls of the outer tank are a conveyance inlet 11a and a conveyance outlet 12a for the treatment substrate W. These are closed by gate valves 410, 420 respectively.

In the interior of the inner tank are located an upper electrode 430 and a lower electrode 440. These are arranged horizontally and in such a manner as to face each other. The upper electrode 430 is supported on the top plate 403 with the aid of an insulator made, for instance, of quartz. The lower electrode 440 is supported on the upper edges of a plurality of rods 460 which can be raised and lowered. The lower electrode 440 is located in such a manner as to divide the interior of the inner tank into a reaction chamber 1A and an exhaust chamber 2A.

The inner tank body 402 is divided horizontally to form an upper body 21a and a lower body 22a. The upper body 21a is supported on the top plate 403. The lower body 22a is supported on the lower electrode 440 with the aid of a supporting body 470. The supporting body 470 forms an L-shaped cross-section, and has a vertical section 471 and a horizontal section 472. The vertical section 471 forms part of the side wall of the inner tank. The horizontal section 472 is attached to the lower electrode 440.

The upper electrode 430 is formed in the shape of a box. The interior of this box-shaped upper electrode 430 forms a gas dispersion unit 431, the purpose of which is to disperse the reaction, cleaning and other gases. To the top plate 432 of this upper electrode 430 is connected a pipe-shaped gas supply unit 480, the purpose of which is to feed the reaction, cleaning and other gases to the gas dispersion unit 431. Meanwhile, there is embedded in this top plate 432 a heater wire 490, the purpose of which is to heat the reaction and cleaning gases along with the facing treatment substrate W. In the bottom plate 433 of this upper electrode 430 is formed a plurality of gas dispersion holes 434. This bottom plate 433 will be referred to below as the ‘gas dispersion plate’.

The lower electrode 440 has an electrode body 441 and a substrate mount 442. The substrate W which is to be treated is mounted on the upper surface of this substrate mount 442 during film deposition. The upper surface of this substrate mount 442 is located in the vicinity of the position where the inner tank is divided. A heater wire 500, the purpose of which is to heat the treatment substrate W during film deposition, is embedded in the electrode body 441.

In the horizontal section 472 of the supporting body 470 of the lower body 22a of the inner tank body 402 is formed a plurality of exhaust holes 31a, the purpose of which is to expel the ambient atmosphere of the reaction chamber 1A into the exhaust chamber 2A.

The bottom plate of the inner tank body 402 is fitted with a pipe-shaped ambient atmosphere exhaust unit 510, the purpose of which is to expel the ambient atmosphere of the exhaust chamber 2A. Similarly, the bottom plate of the outer tank body 401 is fitted with a pipe-shaped ambient atmosphere exhaust unit 520, the purpose of which is to expel the ambient atmosphere which has been expelled from the exhaust chamber 2A by way of the ambient atmosphere exhaust unit 510, along with the ambient atmosphere of the interior of the outer tank. The leading edge of the ambient atmosphere exhaust unit 510 is inserted into the ambient atmosphere exhaust unit 520.

To the gas supply unit 480 is connected a high-frequency 540 power source 280 by way of a direct-current blocking capacitor 530. Thus the upper electrode 430 is connected to the high-frequency power source 540 with the aid of the direct-current blocking capacitor 530. Meanwhile, the outer tank body 401 is earthed. Thus the lower electrode 440 is earthed by way of the inner tank body 402 and the vacuum container 400. This allows high-frequency power to be impressed between the upper electrode 430 and the lower electrode 440 during film deposition.

The plasma CVD device illustrated in the drawing has a plurality of supporting pins 550 to support the treatment substrate W during conveyance in and out. This plurality of supporting pins 550 is attached severally to the upper edges of a plurality of rods 560 which can be raised and lowered. Moreover, the plasma CVD device illustrated in the drawing has a pressure sensor 570 to detect the pressure within the outer tank.

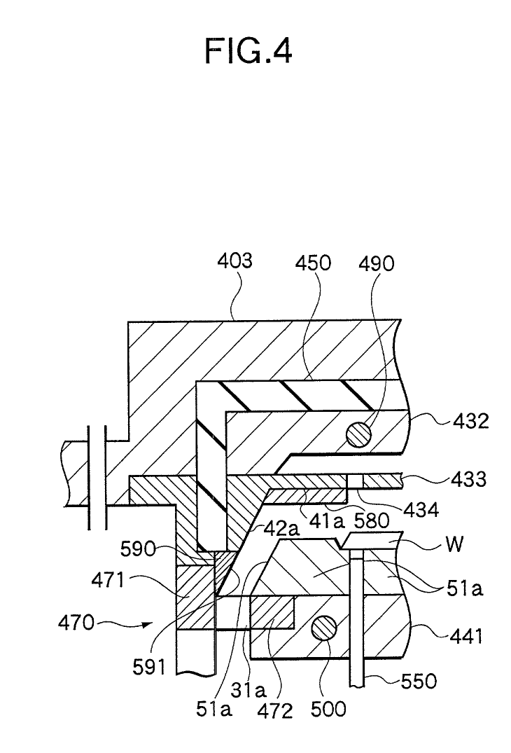

FIG. 4 is a lateral cross-sectional diagram in which the encircled part marked B in FIG. 3 has been enlarged. As will be seen from the drawing, the gas dispersion plate 433 is formed in the shape of an upturned bowl, the edge of which extends below the upper surface of the treatment substrate W mounted on the substrate mount 442. The drawing shows the edge of the gas dispersion plate 213 extending to the vicinity of the upper surface of the substrate mount 442. It also shows this edge extending almost as far as the vertical section 471 of the supporting body 470.

The discharge surface on the edge of the gas dispersion plate 433 is divided into two in the shape of a ring around the centre axis of the upper electrode. The inner discharge surface is fashioned horizontally, while the outer discharge surface is fashioned in such a manner as to form an angle in excess of 90 degrees to the inner discharge surface. The inner discharge surface will be referred to below as the ‘horizontal section 41a’, and the outer discharge surface as the ‘oblique section 42a’. The lateral surface 51a of the substrate mount 442 of the lower electrode 440 is inclined in such a manner as to be parallel with the oblique section 42a.

An insulator 580 formed of alumina or a similar substance is attached to the horizontal section 41a of the discharge surface on the edge of the gas dispersion plate 433, while the oblique section 42a is subjected to insulation treatment by means of alumina spraying, alumite treatment or an equivalent process.

On the edge of the gas dispersion plate 433 is located an insulator 590, which is formed of alumina or a similar substance. This insulator 590 is attached, for instance, to the supporting body 470. The surface 591 of this insulator 590 which comes into contact with the reaction and other gases during film deposition is inclined in such a manner as to be more or less parallel with the lateral surface 51a of the substrate mount 442 of the lower electrode 440. The above is a specific example of the structure.

1.5.2 Action

There follows a description of the actions involved in forming a prescribed thin film on the surface of the treatment substrate W and in gas cleaning with the abovementioned structure. Firstly, the action involved in film deposition will be described.

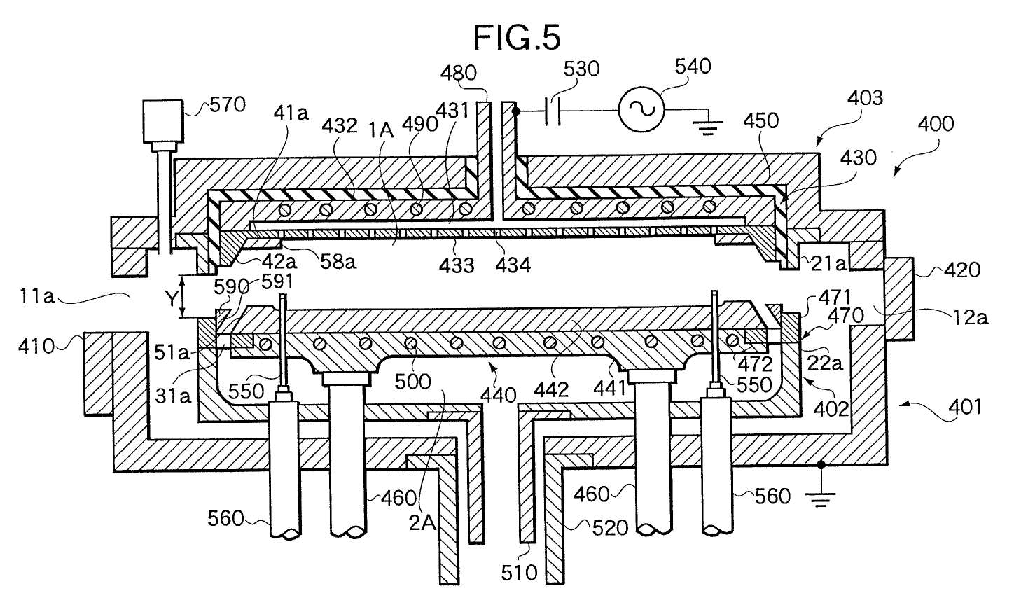

To begin with, as FIG. 5 shows, the gate valve 410 is opened, and the rods 460 are lowered. This allows the lower electrode 440 to be lowered, as a result of which the lower body 221 and supporting body 470 descend and the inner tank opens. Meanwhile, the rods 560 are lowered, and as a result the lift pins 550. However, they are fashioned in such a manner that the amount by which they descend is slightly less than the amount by which the lower electrode 440 descends. This means that the leading edges of the lift pins 550 are located in a position somewhat above the upper surface of the substrate mount 442, as may be seen in FIG. 5.

Next, a substrate conveyance device not shown in the drawing is used to convey the treatment substrate W into the vacuum container 400, where it is mounted on the lift pins 550. The gate valve 410 is then closed, and the rods 460 raised. This allows the lower electrode 440 to be raised, as a result of which the treatment substrate W is transferred from the lift pins 550 to the upper surface of the substrate mount 442.

After this, the lower electrode 440 is raised even further until the upper surface of the vertical section 471 of the supporting body 470 comes into contact with the lower surface of the upper body 21a. In this manner the inner tank is closed. It should be added that at this time the lift pins are also raised to assume the state illustrated in FIG. 3.

Next, the ambient atmosphere contained within the vacuum container 400 is expelled through the ambient atmosphere exhaust units 510, 520. Meanwhile, the ambient atmosphere contained within the outer tank 400 is expelled through the ambient atmosphere exhaust unit 520. This allows the interiors of the inner and outer tanks to assume the state of a predetermined vacuum.

Once the interiors of the inner and outer tanks have assumed the predetermined vacuum state, reaction gas for use in film deposition is fed through the gas supply unit 480 into the gas dispersion unit 431. The reaction gas which has been fed into the gas dispersion unit 431 is now dispersed with the aid of the gas dispersion plate 433 to the area between the upper electrode 430 and the lower electrode 440.

Meanwhile, the ambient atmosphere continues to be expelled from the vacuum container 400. The amount which is expelled is controlled so that the pressure within the inner tank attains the predetermined level. This is achieved indirectly by controlling the pressure within the outer tank, which is monitored with the aid of the pressure sensor 570.

When the pressure within the inner tank reaches the prescribed level, high-frequency power from the high-frequency power source 540 is impressed between the upper electrode 430 and the lower electrode 440. In this manner, plasma is generated between the two electrodes. The molecules of the reaction gas are excited by this plasma, as a result of which the prescribed thin film is formed on the surface of the treatment substrate W.

Once the prescribed thin film has been formed on the surface of the treatment substrate W, the supply of reaction gas is halted. Next, the rods 460 are lowered, as a result of which the lower electrode 440 descends, allowing the inner tank to open. Meanwhile, the treatment substrate W is transferred to the lift pins 550.

After that, the lift pins 550 are lowered to a position where it is possible to remove the treatment substrate W, and the gate valve 420 is opened. Next, the substrate conveyance device which is not shown in the drawing conveys the treatment substrate W, which is resting on the lift pins 550, out of the vacuum container 400 by way of the conveyance outlet 12a. The same treatment is then performed on the next treatment substrate W. and this is repeated with each subsequent treatment substrate W.

The above is the action involved in film deposition. There follows an explanation of the action involved in gas cleaning.

In this case, the ambient atmosphere is expelled from the vacuum container 400 to create a vacuum without mounting a treatment substrate W on the substrate mount 442. Once the interior of the vacuum container 400 has assumed the prescribed vacuum state, cleaning gas for use in gas cleaning is fed through the gas supply unit 480 into the gas dispersion unit 431. The cleaning gas which has been fed into the gas dispersion unit 431 is now dispersed with the aid of the gas dispersion plate 433 to the area between the electrodes 430, 440.

Meanwhile, the ambient atmosphere continues to be expelled from the vacuum container 400. To this end, the amount of ambient atmosphere expelled is controlled so that the pressure within the inner tank may reach the prescribed level. Control is effected in the same manner as during film deposition.

Once the pressure within the inner tank has reached the prescribed level, high-frequency power is impressed between the electrodes 430, 440. This serves to convert the cleaning gas into plasma. The molecules of the cleaning gas are excited by this plasma, so that reaction by-products which have adhered to the thin film formed on the discharge surface of the gas dispersion plate 433 and to the surface 591 of the insulator 590 which comes into contact with the gas are etched. The etched thin film and reaction by-products are expelled by way of the exhaust holes 31a, exhaust chamber 2A and ambient atmosphere exhaust outlets 510, 520. The above is the action involved in gas cleaning.

In the above example, plasma production has been confined to the interior of the inner tank, thus allowing plasma density to be improved in comparison with the case in which a single-tank vacuum container is used. This means that improved efficacy of film deposition and cleaning can be achieved in comparison with the case in which a single-tank vacuum container is used.

Moreover, heat release from the inner tank is inhibited because the interior of the outer tank is decompressed. This means that the interior of the inner tank is maintained in hot wall state, and it is therefore possible to inhibit the adhesion of reaction by-products of poor adhesive strength to the inner wall of the inner tank during film deposition. This makes it possible to inhibit the occurrence of particles.

1.5.3 Effects

The specific example which has been described in detail above allows the following effects to be obtained.

In the first place, the fact that in the present specific example the edge of the gas dispersion plate 433 of the upper electrode 430 extends below the upper surface of the treatment substrate W mounted on the upper surface of the substrate mount 442 of the lower electrode 440 makes it possible to reduce the amount of reaction by-products which are present above the upper surface of the treatment substrate W.

In this manner it is possible to inhibit the occurrence of particles which result from falling reaction by-products. Since this makes it possible to inhibit the adulteration of the treatment substrate W through particle adhesion, it follows that the yield of substrates W can be improved. Moreover, this ability to inhibit the adulteration of the treatment substrate W through particle adhesion makes it possible to extend the maintenance cycle of the plasma CVD device, thus improving throughput.

In the second place, the fact that in the present specific example the insulator 590 is located on the edge of the gas dispersion plate 433 makes it possible to inhibit the occurrence of localised discharge despite the fact that the edge of the dispersion plate 433 extends parallel with the insulator 450.

In the third place, the fact that in the present specific example the surface 591 of the insulator 590 which comes into contact with the gas forms an angle in excess of 90Ε to the horizontal surface means it is possible to ensure that this surface 591 which comes into contact with the gas does not face upwards. In this manner it is possible to prevent reaction by-products adhering to this surface 591 which comes into contact with the gas from rising upwards with vapour currents. As a result it is possible to inhibit the occurrence of particles resulting from rising reaction by-products.

In the fourth place, the fact that in the present specific example the insulator 590 is attached to the supporting body 470 means it is possible to ensure that the surface 591 of the insulator 590 which comes into contact with the gas does not face the conveyance route of the treatment substrate W during conveyance thereof.

This makes it possible during conveyance of the treatment substrate W to prevent reaction by-products adhering to the surface 591 of the insulator 590 which comes into contact with the gas from rising upwards even if vapour currents occur in the vicinity of the insulator 590 as a result of this conveyance of the treatment substrate W. In this manner it is possible to inhibit the occurrence of particles resulting from rising reaction by-products.

In the fifth place, the fact that in the present specific example the discharge surface on the edge of the gas dispersion plate 433 is insulated makes it possible to inhibit discharge in the neighbourhood of the treatment substrate W despite the fact that the edge of the gas dispersion plate 433 is extended. This in turn makes it possible to ensure that plasma density above the treatment substrate W is not reduced. The consequent ability to prevent reduced efficacy of plasma treatment above the treatment substrate W means it is possible to ensure that there is no deterioration in the distributional characteristics of film thickness.

In the sixth place, the fact that in the present specific example the discharge surface on the edge of the gas dispersion plate 433 is insulated also makes it possible essentially to inhibit any increase in the area of the discharge surface despite the fact that the edge of the gas dispersion plate 433 extends further than conventionally. This in turn makes it possible to ensure that there is no increased film stress caused by the introduction of large amounts of electrons into the thin film which is formed on the surface of the treatment substrate W. As a result, it is possible to prevent peeling of the thin film from the surface of the treatment substrate W.

In the seventh place, the fact that in the present specific example insulation of the horizontal section 41a of the discharge surface on the edge of the gas dispersion plate 433 is implemented with the aid of an insulator 580 makes it possible to enhance the effect of inhibiting discharge in the neighbourhood of the treatment substrate W as compared with insulation through insulation treatment.

In the eighth place, the fact that in the present specific example insulation of the oblique section 42a of the discharge surface on the edge of the gas dispersion plate 433 is implemented with the aid of insulation treatment makes it possible, more effectively than would be the case if it were insulated by means of an insulator, to ensure that there is no adhesion of reaction by-products of poor adhesive strength to the insulator 580. In addition, this structure makes it possible to ensure that there is no adhesion of reaction by-products of poor adhesive strength to the oblique section 42a either. This is because a structure of this sort makes it possible to guarantee a plasma density at which adhesion of reaction by-products to the oblique section 42a can be prevented.

In the ninth place, the fact that in the present specific example the discharge surface on the edge of the gas dispersion plate 433 becomes progressively broader as it proceeds downwards means that there is no risk of obstruction of the flow of cleaning gas at the edge of this gas dispersion plate 433 during gas cleaning despite the fact that it extends downwards. As a result, film which has formed on the discharge surface of the upper electrode can easily be removed by means of gas cleaning with plasma.

In the tenth place, the fact that in the present specific example the surface 591 of the insulator 590 which comes into contact with the reaction gas during film deposition is the same oblique surface as the oblique section 42a of the gas dispersion plate 433 allows the surface 591 which comes into contact with the reaction gas to form an extension of the oblique section 42a. This makes it possible to ensure than there is no risk of obstruction of the flow of gas on this surface 591 which comes into contact with the reaction gas. As a result, it is possible to inhibit adhesion of reaction by-products to this surface 591 during film deposition, and during gas cleaning to etch effectively those reaction by-products which have adhered to it. This means that the time required for gas cleaning can be shortened.

In the eleventh place, the fact that in the present specific example the upper surface of the substrate mount 442 of the lower electrode 440 is located in the vicinity of the substrate conveyance route means that it is possible to decrease the width of the aperture Y (cf. FIG. 5) of the vacuum container 200.

In the twelfth place, the fact that in the present specific example the interior of the reaction chamber 1A is maintained at a high temperature with the aid of the heater wires 490, 500 makes it possible to inhibit the creation of dust from deposits (thin film, reaction by-products etc.) which form in the interior of the reaction chamber 1A as a result of film deposition.

2. Second Embodiment

2.1 Structure

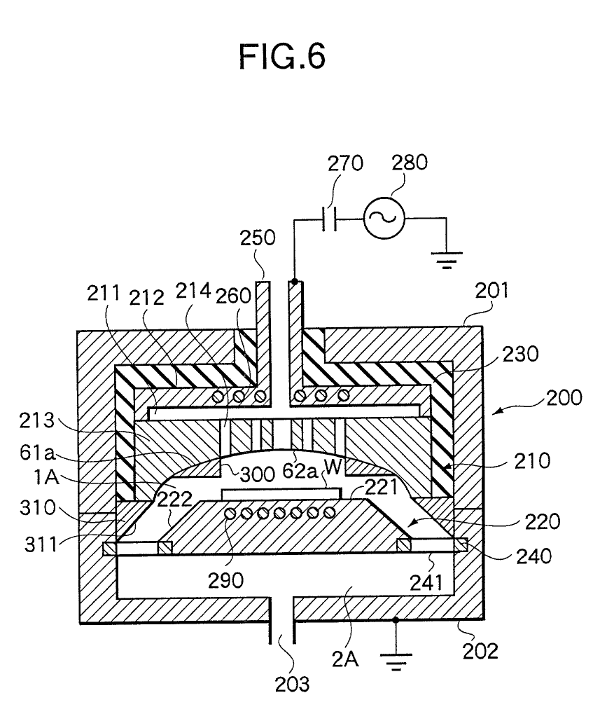

FIG. 6 is a lateral cross-sectional diagram illustrating a second embodiment of the plasma CVD device to which the present invention pertains. In FIG. 6 those parts which have more or less the same function as those in FIG. 1 are have been allocated the same codes, and a detailed description will be omitted.

It has been described how in the first embodiment it the discharge surface on the edge of the gas dispersion plate 213 is extended first horizontally and then at an angle in excess of 90 degrees to the horizontal section 1a, so as to become progressively broader as it proceeds downwards. In the present embodiment, as FIG. 6 shows, the discharge surface 61a on the edge of the gas dispersion plate 213 is instead extended so as to form a concave curved surface, thus ensuring that this discharge surface 61a becomes progressively broader as it proceeds downwards.

2.2 Effects

This structure also makes it possible to prevent gas from being retained on the discharge surface 61a on the edge of the gas dispersion plate 213, thus reducing the amount of thin film which adheres to this discharge surface 61a during film deposition, while during gas cleaning it facilitates the effective etching of such thin film as has adhered.

### 2.3 MODIFIED EXAMPLE

FIG. 6 illustrates an example in which not only the discharge surface 61a on the edge of the gas dispersion plate 213 but also the discharge surface 62a in the centre of the gas dispersion plate 213 forms a concave curved surface. However, in the present embodiment as in the first embodiment, it is also possible for the discharge surface 62a in the centre of the gas dispersion plate 213 to be horizontal and flat in shape, while only the discharge surface 61a on the edge of the plate forms a concave curved surface.

### 2.4 SPECIFIC EXAMPLE

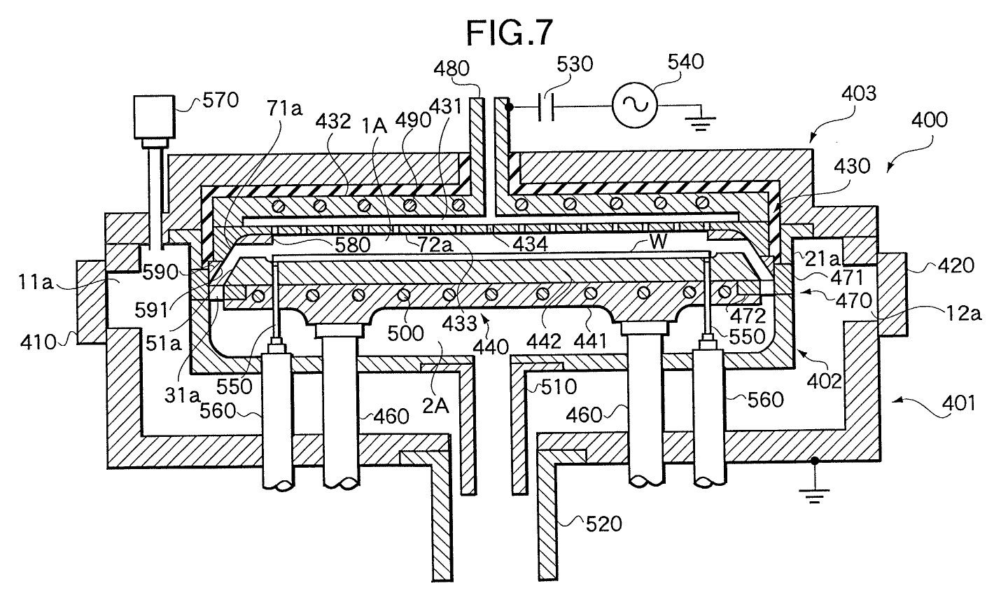

FIG. 7 is a lateral cross-sectional diagram illustrating an example of the detailed structure of the second embodiment. As with the example illustrated in FIG. 3, the present embodiment has here been applied to a plasma CVD device having a vacuum container of twin-tank structure. In FIG. 7 those parts which have more or less the same function as those in FIG. 3 have been allocated the same codes, and a detailed description will be omitted.

As FIG. 7 shows, the present example is fashioned in such a manner that the discharge surface 71a on the edge of the gas dispersion plate 433 forms a concave curved surface, as a result of which the discharge surface 71a becomes progressively broader as it proceeds downwards. In the example illustrated in FIG. 7 the discharge surface 72a in the centre of the gas dispersion plate 433 is flat in shape.

3. Third Embodiment

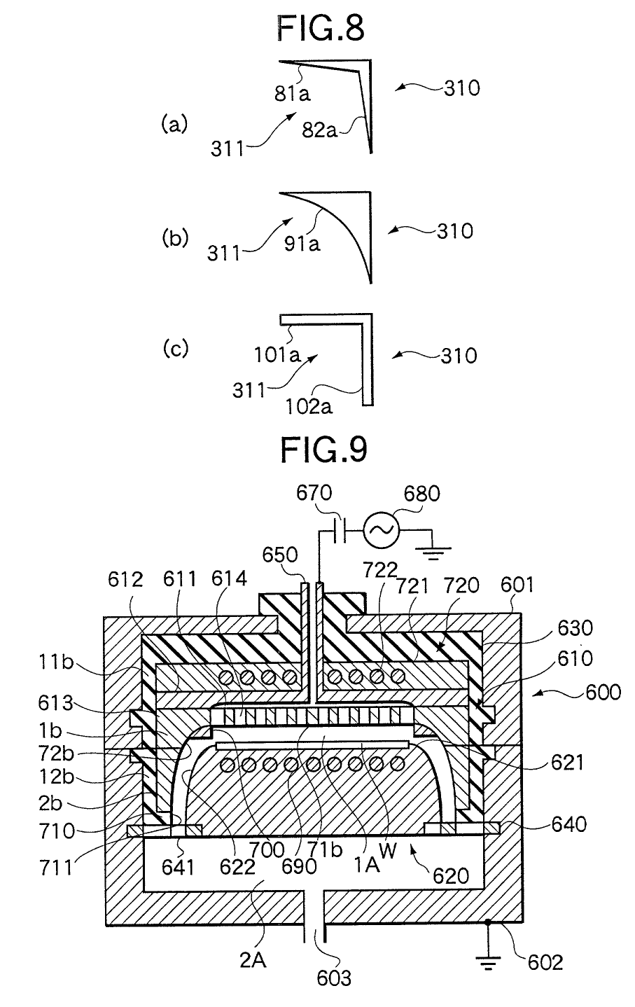

FIG. 8 is a lateral cross-sectional diagram illustrating a third embodiment of the plasma CVD device to which the present invention pertains.

In the examples described in the foregoing embodiments, the surface 311 of the insulator 310 which comes into contact with the gas comprises a single surface forming an angle in excess of 90E to the horizontal surface. In contrast to this, the surface 311 which comes into contact with the gas in the example illustrated in FIG. 8(a) constitutes a combination of two surfaces 81a, 82a which form angles in excess of 90 degrees to the horizontal surface and are inclined differently from each other. Meanwhile, in the example illustrated in FIG. 8(b) the surface 311 which comes into contact with the gas forms a single concave curved surface. Moreover, in the example illustrated in FIG. 8(c) the surface 311 which comes into contact with the gas constitutes a combination of a horizontal surface 101a and a vertical surface 102a.

A structure of this sort makes it possible to ensure that the surface 311 of the insulator 310 which comes into contact with the gas does not face upwards. In this manner it is possible to prevent reaction by-products adhering to this surface 311 which comes into contact with the gas from rising upwards with vapour currents. As a result it is possible to inhibit the occurrence of particles resulting from rising reaction by-products. It goes without saying that the insulator 310 here is interchangeable with the insulator 590 of the device illustrated in FIG. 3.

4. Fourth Embodiment

4.1 Structure

FIG. 9 is a lateral cross-sectional diagram illustrating a fourth embodiment of the plasma CVD device to which the present invention pertains. It should be added that FIG. 9 shows a typical example of a case in which the present invention is applied to a plasma CVD device having a vacuum container of single-tank structure.

In the examples described in the foregoing embodiments, the edge of the gas dispersion plate 213 extends almost as far as the position where the vacuum container 200 is divided. In contrast to this, the edge of the gas dispersion plate in the present embodiment extends below the position where the vacuum container is divided. This makes it possible to reduce the number of falling particles which come about when reaction by-products adhering below this edge rise upwards. Moreover, the fact that in the present embodiment the edge of the gas dispersion plate is divided horizontally in the vicinity of the position where the vacuum container is divided, thus allowing the edge of the gas dispersion plate to extend below the position where the vacuum container is divided, means that it is possible to avoid any increase in the width of the aperture of the vacuum container.

There follows, with reference to FIG. 9, a detailed description of the structure of the plasma CVD device of the present embodiment. With the exception of the structure of the gas dispersion plate, the structure of the plasma CVD device illustrated in FIG. 9 is basically more or less the same as that illustrated in FIG. 1.

In other words, the plasma CVD device illustrated in FIG. 9 has a vacuum container 600 in the same way as the plasma CVD device illustrated in FIG. 1. This vacuum container has an upper container 601 and a lower container 602. The upper container 601 is fixed in a predetermined position, while the lower container 602 can be raised and lowered with the aid of a raising and lowering mechanism which is not shown in the drawing.

Within the vacuum container 600 are located an upper electrode 610 and a lower electrode 620, constituting a pair of parallel flat electrodes. The upper electrode 610 is supported on the upper container 601 with the aid of an insulator 630, while the lower electrode 620 is supported on the lower container 602 with the aid of a supporting plate 640.

To the top plate 612 of the upper electrode 610 is connected a gas supply unit 650, while there is located on this top plate 612 a heater 720. The structure of this heater 720 is such that a heater wire 722 is embedded within a heater body 721. In the bottom plate of the upper electrode 610, which is to say in the gas dispersion plate 613, is formed a plurality of gas dispersion holes 614.

The upper surface of the lower electrode 620, which is to say the substrate-mounting surface 621, is located in the vicinity of the position where the vacuum container 600 is divided. In other words, it is located in the vicinity of the substrate conveyance route. A heater wire 690 is embedded in this lower electrode 620. In the supporting plate 640 of the lower electrode 620 is formed a plurality of exhaust holes 641, the purpose of which is to expel the ambient atmosphere of the reaction chamber 1A into the exhaust chamber 2A. Meanwhile, in the bottom plate of the vacuum container 600 is formed an exhaust hole 603, the purpose of which is to expel the ambient atmosphere of the exhaust chamber 2A. To the gas supply unit 650 is connected a high-frequency power source 680 by way of a direct-current blocking capacitor 670, and the lower container 602 is earthed.

The edge of the gas dispersion plate 613 extends below the position where the vacuum container 600 is divided. In other words, it extends below the substrate conveyance route. The drawing shows it extending as far as the vicinity of the supporting body 640 of the vacuum container 600. The edge of this gas dispersion plate 613 is divided horizontally in the vicinity of the position where the vacuum container 600 is divided. In other words, it is divided horizontally in the vicinity of the substrate conveyance route. As a result the gas dispersion plate 613 has an upper gas dispersion plate 1b and a lower gas dispersion plate 2b.

In line with this, the insulator 630 is also divided horizontally in the vicinity of the position where the vacuum container 600 is divided. As a result the insulator 630 has an upper insulator 11b and a lower insulator 12b.

Along with the heater 720, the upper gas dispersion plate 1b is supported on the upper container 601 with the aid of the upper insulator 11b. Similarly, the lower gas dispersion plate 2b is supported on the lower container 602 with the aid of the lower insulator 12b.

The discharge surface 71b in the centre of the gas dispersion plate 613 is, for instance, flat in shape. In contrast to this, the discharge surface 72b on the edge is, for instance, shaped in such a manner as to form a concave curved surface. In line with this, the lateral surface 622 of the lower electrode 620 is shaped in such a manner as to form a convex curved surface more or less parallel to the discharge surface 72b on the edge of the gas dispersion plate 613.

Meanwhile, the discharge surface 72b on the edge of the gas dispersion plate 613 is insulated by means of a combination of the insulator 700 and insulation treatment. The insulator 710, which serves to prevent localised discharge on the edge of the gas dispersion plate 613, is formed by extending the insulator 630. The surface 711 of this insulator 710 which comes into contact with the gas is fashioned in such a manner as to form an extension of the discharge surface 72b on the edge of the gas dispersion plate 613. The above is the structure of the fourth embodiment.

4.2 Effects

The embodiment which has been described in detail above allows the following effects to be obtained.

In the first place, the fact that in the present embodiment the edge of the gas dispersion plate 613 extends below the position where the vacuum container 600 is divided makes it possible to inhibit the occurrence of particles caused by rising reaction by-products which had adhered below the edge of the gas dispersion plate 613 (e.g. reaction by-products which had adhered to the surface 711 of the insulator 710 which comes into contact with the gas).

In the second place, the fact that in the present embodiment the edge of the gas dispersion plate 613 is divided in the vicinity of the position where the vacuum container 600 is divided makes it possible to avoid any increase in the width of the aperture of the vacuum container 600 during substrate conveyance despite the fact that the edge of the dispersion plate 613 extends below the position where the vacuum container 600 is divided.

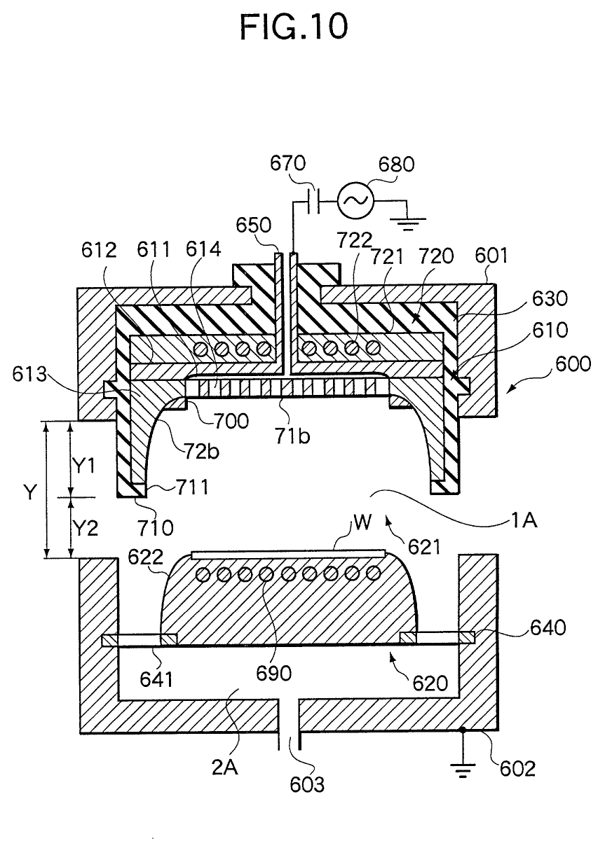

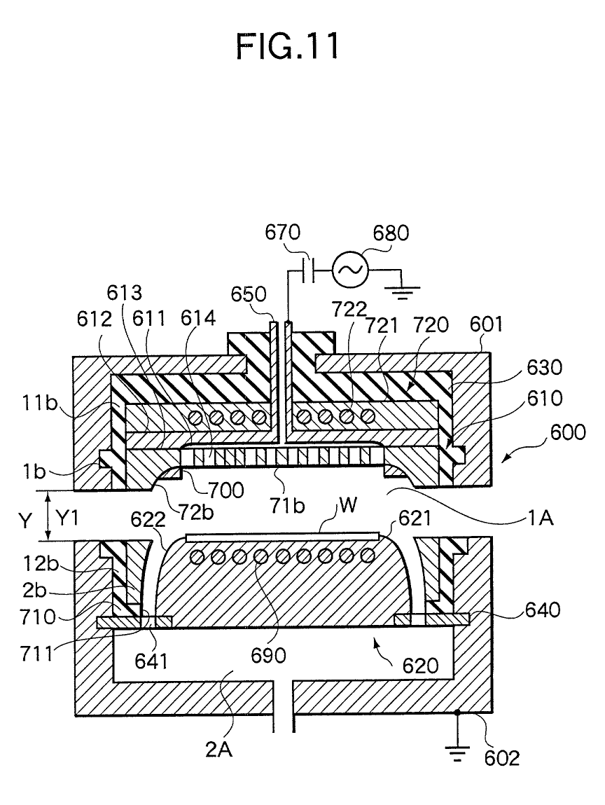

That is to say, if the dispersion plate 613 were not divided, the width Y of the aperture of the vacuum container 600 would need to be Y1+Y2, as is shown in FIG. 10. Here, Y1is the length of that portion of the insulator 630 which protrudes from the upper receptacle 601, while Y2 is the width of the aperture which would be required if this protruding section were absent. In contrast, as may be seen from FIG. 11, dividing the dispersion plate 613 in accordance with the present embodiment means that only Y2 is required as the width of the aperture Y, and Y1 can be dispensed with. Thus, the present embodiment makes it possible to avoid any increase in the width of the aperture of the vacuum container 600 during substrate conveyance despite the fact that the edge of the dispersion plate 613 extends below the position where the vacuum container 600 is divided.

### 4.3 SPECIFIC EXAMPLE

4.3.1 Structure

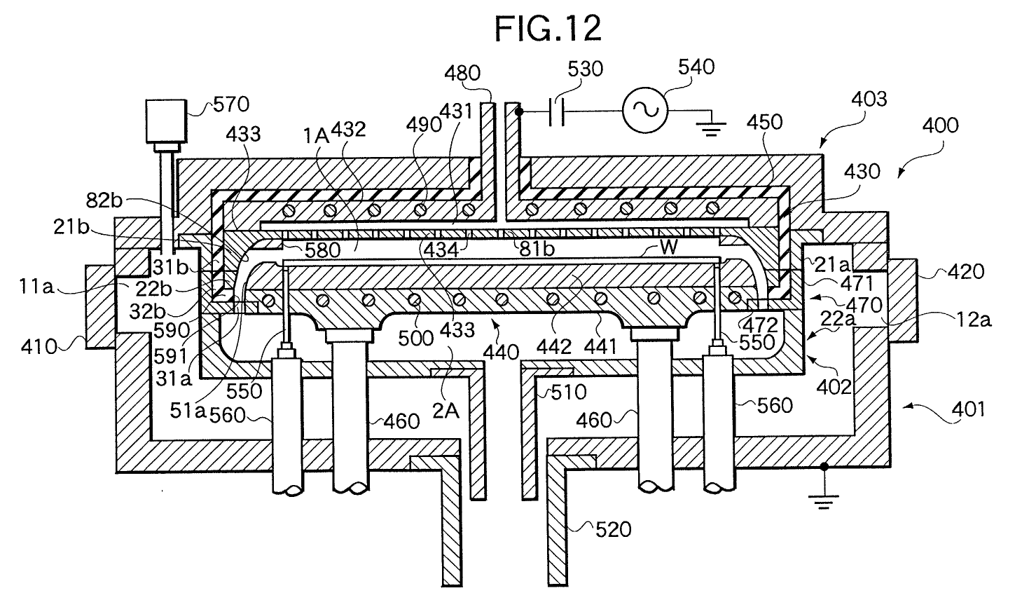

FIG. 12 is a lateral cross-sectional diagram illustrating an example of the detailed structure of the fourth embodiment. The drawing shows a typical example of a case in which the present embodiment has been applied to a plasma CVD device having a vacuum container of twin-tank structure as illustrated in FIG. 3. In FIG. 12 those parts which have more or less the same function as those in FIG. 3 have been allocated the same codes, and a detailed description will be omitted.

As FIG. 12 shows, the edge of the gas dispersion plate 433 in the present specific example of a plasma CVD device extends below the position where the inner tank is divided (the position of the boundary between the upper body 21a of the inner tank and the vertical section 471 of the supporting body 470). In other words, it extends below the substrate conveyance route. In the drawing it is shown extending as far as the vicinity of the horizontal section 472 of the supporting body 470.

Moreover, the edge of this gas dispersion plate 433 is divided horizontally in the vicinity of the position where the inner tank is divided. As a result the gas dispersion plate 433 has an upper gas dispersion plate 21b and a lower gas dispersion plate 22b.

In line with this, the insulator 430 is also divided horizontally in the vicinity of the position where the inner tank is divided. As a result the insulator 450 has an upper insulator 31b and a lower insulator 32b.

The upper gas dispersion plate 21b is supported on the upper body 21a of the inner tank with the aid of the upper insulator 31b. Similarly, the lower gas dispersion plate 22b is supported on the vertical section 471 of the supporting body 470 with the aid of the lower insulator 32b.

The insulator 590 (cf. FIG. 3), the purpose of which is to prevent localised discharge on the edge of the gas dispersion plate 433, is formed by extending edge of the lower insulator 32b in a horizontal direction. In contrast, the discharge surface 82b of the edge is fashioned in such a manner as to form a concave curved surface. In line with this, the lateral surface 51a of the lower electrode 440 is shaped in such a manner as to form a convex curved surface more or less parallel to the discharge surface on the edge of the gas dispersion plate 443. Meanwhile, the discharge surface 82b on this edge is insulated by means of a combination of an insulator and insulation treatment. The above is the structure of the present specific example.

4.3.2 Effects

The specific example which has been described in detail above allows the following effects to be obtained.

In the first place, the fact that in the present specific example the edge of the gas dispersion plate 433 extends below the position where the inner tank is divided makes it possible to inhibit the occurrence of particles caused by rising reaction by-products which had adhered below the edge of the gas dispersion plate 433 (eg reaction by-products which had adhered to the surface 591 of the insulator 590 which comes into contact with the gas).

In the second place, the fact that in the present specific example the edge of the gas dispersion plate 433 is divided in the vicinity of the position where the inner tank is divided makes it possible to avoid any increase in the width of the aperture of the inner tank during substrate conveyance despite the fact that the edge of the dispersion plate 433 extends below the position where the inner tank is divided.

5. Fifth Embodiment

5.1 Structure

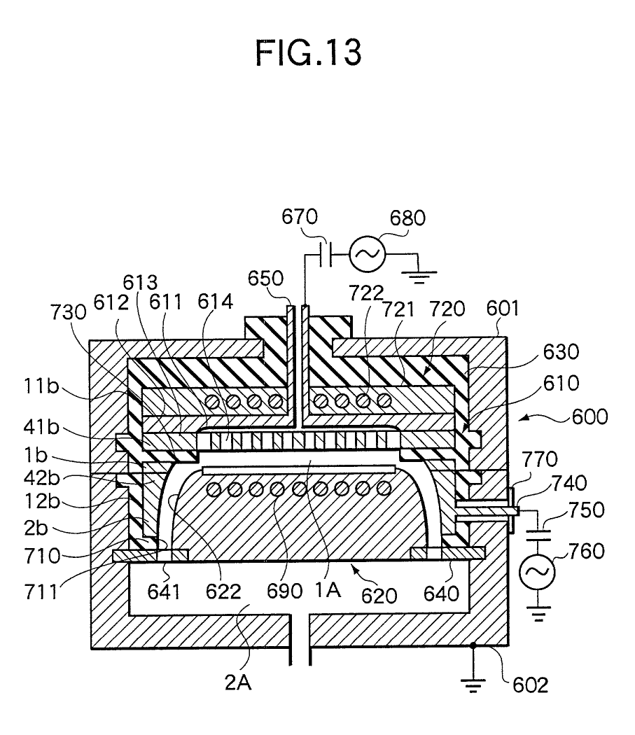

FIG. 13 is a lateral cross-sectional diagram illustrating a fifth embodiment of the plasma CVD device to which the present invention pertains. In FIG. 13 those parts which have more or less the same function as those in FIG. 11 have been allocated the same codes, and a detailed description will be omitted.

The fourth embodiment has described power is supplied to the gas dispersion plate 613 from a single high-frequency power source 680. In contrast to this, the gas dispersion plate 613 in the present embodiment is divided, for instance, into a flat section 41b and a tubular section 42b, power being supplied to each of these independently with the aid of two high-frequency power sources 680, 760.

In this case, the flat section 41b and the tubular section 42b are divided by means of an insulator 730. This insulator 730 is formed, for instance, by modifying the insulator 630. What is more, this insulator 730 doubles as the insulator 700 (cf. FIG. 9) which is attached to the discharge surface on the edge of the gas dispersion plate 613.

The supply terminal 740 on the tubular section 42b is led out of the vacuum container 600 by way of the lower insulator 12b and the lower container 602. This supply terminal 740 is formed, for instance, by modifying the tubular section 42b. The high-frequency power source 760 is connected to the supply terminal 740 by way of the direct-current blocking capacitor 750. In this case, the supply terminal 740 is insulated to the lower container 602 with the aid of the insulator 770. This insulator 770 is formed by modifying the lower insulator 12b.

5.2 Effects

In the present embodiment, which has been described in detail above, the fact that the gas dispersion plate 613 is divided into a flat section 41b and a tubular section 42b, power being supplied independently to each, makes it possible to supply them with differing amounts of power. This means that during cleaning it is possible to supply a greater amount of power to the tubular section 42b where cleaning is slow than to the flat section 41b where it is quicker, thus allowing cleaning to be implemented with increased efficiency.

### 5.3 SPECIFIC EXAMPLE

5.3.1 Structure

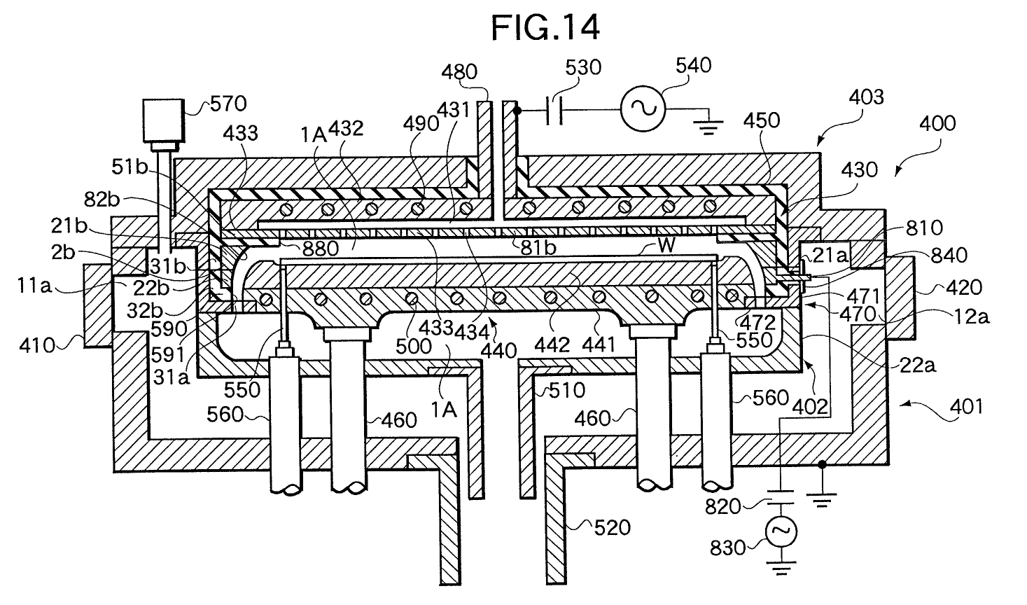

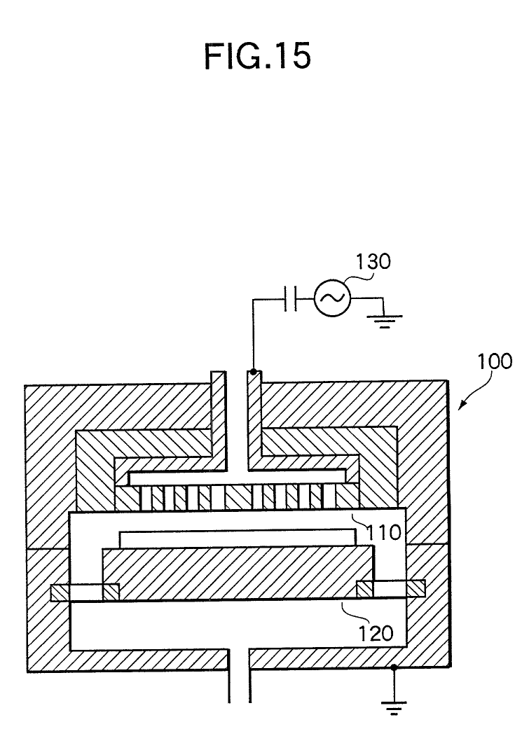

FIG. 14 is a lateral cross-sectional diagram illustrating the detailed structure of the present embodiment. The drawing shows a typical example of a case in which the present embodiment has been applied to a plasma CVD device of twin-tank structure as illustrated in FIG. 3. In FIG. 14 those parts which have more or less the same function as those in FIG. 3 have been allocated the same codes, and a detailed description will be omitted.

As may be seen from FIG. 14, the gas dispersion plate 433 in the plasma CVD device of the present embodiment is not only divided in the vicinity of the position where the inner tank is divided, but is also divided into a flat section 51b and a tubular section 52b. The flat section 51b and the tubular section 52b are divided by means of an insulator 800. This insulator 800 is formed by modifying the upper insulator 31b. What is more, this insulator 800 doubles as the insulator 580 (cf. FIG. 3) which is attached to the discharge surface on the edge of the gas dispersion plate 433.

The supply terminal 810 on the tubular section 52b is led out of the inner tank by way of the insulator 430 and the vertical section 471 of the supporting body 470. This supply terminal 810 is formed by modifying the tubular section 52b. The high-frequency power source 830 is connected to this supply terminal 810 by way of the direct-current blocking capacitor 820. In this case, the supply terminal 810 is insulated to the vertical section 471 of the supporting body 470 with the aid of the insulator 840. This insulator 840 is formed by modifying the lower insulator 32b.

5.3.2 Effects

In the present specific example, which has been described in detail above, the fact that the gas dispersion plate 433 is divided into a flat section 51b and a tubular section 52b, power being supplied independently to each, makes it possible to supply them with differing amounts of power. This means that during cleaning it is possible to supply a greater amount of power to the tubular section 52b where cleaning is slow than to the flat section 51b where it is quicker, thus allowing cleaning to be implemented with increased efficiency.

6. Other Embodiments

Five embodiments of the present invention have been described above, but the present invention is in no way restricted to the embodiments which have been described above.

For instance, the examples described in the foregoing embodiments have shown how for the purpose of insulation the discharge surface on the edge of the gas dispersion plate has been divided into two in the shape of a ring around the centre axis of the plate, the inner discharge surface being insulated by means of an insulator, and the outer discharge surface by means of insulation treatment.

However, the present invention also permits of insulating the inner discharge surface by means of insulation treatment, and the outer discharge surface by means of an insulator. Alternatively, the whole discharge surface may be insulated by means of an insulator or by means of insulation treatment.

Moreover, the fifth embodiment has shown how gas the dispersion plate has been divided for the purpose of power supply into two power supply areas. However, the present invention also permits of dividing it into three or more power supply areas, power being supplied independently to each.

Again, the examples described in the foregoing embodiments have explained the present invention as applied to a plasma CVD device which employs a high-frequency power source for the purpose of creating plasma. However, the present invention can also be applied to plasma CVD devices which employ a direct-current or other type of power source rather than a high-frequency one.

Apart from this, it goes without saying that the present invention can be modified in various ways provided that they do not deviate from the essential gist thereof.

As has been explained above, the fact that in the plasma CVD device according to claim 1 the edge of the upper electrode extends below the upper surface of the treatment substrate located on the upper surface of the lower electrode makes it possible to reduce the amount of reaction by-products of poor adhesive strength which are present on the treatment substrate. In this manner it is possible to inhibit the occurrence of particles which result from falling reaction by-products. Since this makes it possible to inhibit the adulteration of the treatment substrate through particle adhesion, it follows that the yield of substrates W can be improved.

Meanwhile, the fact that in the plasma CVD device according to claim 2 an insulator is located on the edge of the upper electrode makes it possible to prevent the occurrence of localised discharges on this edge.

Moreover, the fact that in the plasma CVD device according to claim 3 the insulator is fashioned in such a manner that the surface which comes into contact with the gas does not face upwards makes it possible during film deposition to prevent reaction by-products adhering to the surface which comes into contact with the gas from rising upwards with vapour currents. In this manner it is possible to inhibit the occurrence of particles resulting from rising reaction by-products.

Furthermore, the fact that in the plasma CVD device according to claim 4 the insulator is fashioned in such a manner that the surface which comes into contact with the gas does not face the conveyance route of this treatment substrate during conveyance thereof makes it possible during conveyance of the treatment substrate to prevent reaction by-products adhering to the surface which comes into contact with the gas from rising upwards even if vapour currents occur in the vicinity of the insulator as a result of this conveyance. In this manner it is possible to inhibit the occurrence of particles resulting from rising reaction by-products.

Again, the fact that in the plasma CVD device according to claim 5 the discharge surface on the edge of the upper electrode is insulated makes it possible to inhibit discharge in the neighbourhood of the treatment substrate. This in turn makes it possible to ensure that plasma density above the treatment substrate is not reduced in spite of the increased area of the a discharge surface which results from the extension on the edge of the upper electrode. The consequent ability to prevent reduced efficacy of plasma treatment above the treatment substrate means it is possible to ensure that there is no deterioration in the distributional characteristics of film thickness.

Moreover, this structure makes it possible to prevent increased introduction of electrons into the thin film which is formed on the surface of the treatment substrate. This in turn makes it possible to ensure that there is no increased film stress caused by the introduction of large amounts of electrons. As a result, it is possible to prevent peeling of the thin film which is formed on the surface of the treatment substrate.

In addition, the fact that in the plasma CVD device according to claim 6 insulation of the inner discharge surface is implemented with the aid of an insulator makes it possible to enhance the effect of inhibiting discharge in the neighbourhood of the treatment substrate as compared with insulation through insulation treatment.

Moreover, the fact that insulation of the outer discharge surface in this plasma CVD device is implemented with the aid of insulation treatment makes it possible, more effectively than would be the case if it were insulated by means of an insulator, to ensure that there is no adhesion of reaction by-products of poor adhesive strength around the insulator which is located on the inner discharge surface.

Yet again, the fact that in the plasma CVD device according to claim 7 the discharge surface on the edge of the upper electrode becomes progressively broader as it proceeds downwards means that there is no risk of obstruction of the flow of cleaning gas at the edge of this upper electrode during gas cleaning despite the fact that it extends downwards. As a result, film which has formed on the discharge surface of the upper electrode can easily be removed by means of gas cleaning with plasma.

What is more, the fact that in the plasma CVD device according to claim 8 the insulator is fashioned in such a manner that the surface which comes into contact with the reaction gas during film deposition forms an extension of the discharge surface on the edge of the upper electrode makes it possible to ensure than there is no risk of obstruction of the flow of gas on this surface which comes into contact with the reaction gas. As a result, it is possible to inhibit adhesion of reaction by-products to this surface during film deposition, and to etch effectively those reaction by-products which have adhered to it during gas cleaning. This means that the time required for gas cleaning can be shortened.

Further still, the fact that in the plasma CVD device according to claim 9 the edge of the upper electrode extends below the conveyance route of the treatment substrate and is divided horizontally in the vicinity of this conveyance route makes it possible to avoid widening the aperture of the vacuum container during substrate conveyance in spite of the fact that the edge of the upper electrode extends below the conveyance route of the treatment substrate.

Additionally, the fact that in the plasma CVD device according to claim 10 the upper electrode is divided horizontally in one place or more and power is supplied independently to each divided area means that during gas cleaning of the interior of the vacuum container with plasma it is possible to supply a greater amount of power to those parts where cleaning is slow. This allows cleaning to be implemented with increased efficiency.

Finally, the plasma CVD device according to claim 11 allows the effects of the present invention to be achieved in a device which employs a vacuum container of twin-tank structure.

What is claimed is:

1. A plasma CVD device which impresses electric power between an upper electrode and a lower electrode arranged horizontally so as to face each other, thus producing plasma from reaction gases for use in film deposition, said reaction gases being excited by this plasma to form a prescribed thin film on the surface of a treatment substrate located on the upper surface of said lower electrode, wherein:
the edge of said upper electrode extends below the upper surface of said treatment substrate located on the upper surface of said lower electrode.

2. The plasma CVD device according to claim 1, wherein an insulator is located on the edge of said upper electrode.

3. The plasma CVD device according to claim 2, wherein said insulator is fashioned in such a manner that of a plurality of surfaces thereof the surface which comes into contact with said reaction gas during film deposition does not face upwards.

4. The plasma CVD device according to claim 2, wherein said insulator is fashioned in such a manner that of a plurality of surfaces thereof the surface which comes into contact with said reaction gas during film deposition does not face the conveyance route of this treatment substrate during conveyance thereof.

5. The plasma CVD device according to claim 1, wherein the discharge surface of the edge of said upper electrode is insulated.

6. The plasma CVD device according to claim 5, wherein the discharge surface of the edge of said upper electrode is divided into two discharge surfaces in the shape of a ring around the centre axis of said upper electrode, the inner discharge surface being insulated by means of an insulator while the outer discharge surface is insulated by means of insulating treatment.

7. The plasma CVD device according to claim 1, wherein the discharge surface of the edge of said upper electrode becomes progressively broader as it proceeds downwards.

8. The plasma CVD device according to claim 2, wherein said insulator is fashioned in such a manner that of a plurality of surfaces thereof the surface which comes into contact with said reaction gas during film deposition forms the extension of the discharge surface on the edge of said upper electrode.

9. The plasma CVD device according to claim 1, wherein the edge of said upper electrode extends below the conveyance route of said treatment substrate and is divided horizontally in the vicinity of this conveyance route.

10. The plasma CVD device according to claim 1, wherein said upper electrode is divided horizontally in one place or more and electric power is supplied independently to each divided area.

11. The plasma CVD device according to claim 1, wherein the vacuum container for use in film deposition is of a twin-tank structure having an inner tank and an outer tank, said upper electrode and said lower electrode being located within the inner tank.
